(19) United States
(12) Patent Application Publication
(10) Pub. No.: US 2024/0262963 A1
(43) Pub. Date: Aug. 8, 2024

(54) POLYIMIDE COMPOSITION, METHOD FOR PREPARING THE SAME, POLYIMIDE FILM AND FLEXIBLE COPPER CLAD LAMINATE

(71) Applicant: NexFlex Co., Ltd., Chungcheongbuk-do (KR)

(72) Inventors: So Jeong KIM, Daejeon (KR); Joo Young KIM, Sejong-si (KR); Hyuk Jun KIM, Daejeon (KR)

(73) Assignee: NexFlex Co., Ltd., Chungcheongbuk-do (KR)

(21) Appl. No.: 18/411,220

(22) Filed: Jan. 12, 2024

(30) Foreign Application Priority Data
Feb. 3, 2023 (KR) 10-2023-0014828

(51) Int. Cl. C08G 73/10; C08J 5/18

(52) U.S. Cl. CPC C08G 73/1053; C08G 73/1032; C08J 5/18; C08J 2379/08

(57) ABSTRACT

A polyimide composition, a method of preparing the polyimide composition, a polyimide film, and a flexible copper clad laminate are provided. The polyimide composition includes a dianhydride, and a diamine, and the diamine comprises an aromatic diamine, and an aliphatic diamine.

### CROSS-REFERENCE TO RELATED APPLICATION

This application claims the benefit of Korean Patent Application No. 10-2023-0014828 filed on Feb. 3, 2023, in the Korean Intellectual Property Office, the entire disclosure of which is incorporated herein by reference for all purposes.

### BACKGROUND

### 1. Field of the Invention

One or more embodiments relate to a polyimide composition, a method of preparing the polyimide composition, a polyimide film, and a flexible copper clad laminate (FCCL).

### 2. Description of the Related Art

A flexible printed circuit board (FPCB), which is a type of printed board, may have flexibility and may be repeatedly deformed by bonding a thin copper foil and an insulating film. Since the FPCB is thin and suitable for use in a movable portion, the demand for the FPCB is increasing as an essential material for miniaturization, lightening, and thinness of electronic devices. A flexible copper clad laminate (FCCL), a basic raw material of an FPCB, typically has a structure in which a copper foil and polyimide are laminated. The FCCL is a core raw material required for the manufacture of a flexible circuit board and is being spotlighted as a core material for precision electronic components due to excellent heat resistance, flex resistance, and chemical resistance thereof, and easy workability thereof.

Polyimide (PI) is a polymer material having excellent mechanical strength, chemical resistance, weather resistance, and heat resistance based on chemical stability of an imide ring. In addition, since polyimide has excellent electrical properties such as insulating properties and low dielectric constant, numerous studies have been conducted to use polyimide as a lightweight and flexible polymer substrate material. Since polyimide is a core raw material for flexible circuit boards and FCCLs used in various electronic devices, research regarding polyimide is also being actively conducted as technology for flexible circuit boards, core components of next-generation smart devices, is actively under development.

To manufacture an FCCL with excellent performance, a copper foil that is a material for a conductive layer and polyimide that is a material for an insulating layer need to be bonded, instead of using an adhesive layer, and thus, a high adhesive strength therebetween is required. However, polyimide that does not have a polar group on a surface thereof is peeled off from a metal due to a decrease in durability based on the adhesion tendency caused by a low adhesive strength to the metal. As a result, for polyimide with a low adhesive strength to the copper foil, a separate material and process for a polyimide adhesive layer are required. In addition, existing polyimide has a disadvantage in bending evaluation due to a low yield point and elongation thereof.

The above description has been possessed or acquired by the inventor(s) in the course of conceiving the present disclosure and is not necessarily an art publicly known before the present application is filed.

### SUMMARY

One or more embodiments provide a polyimide composition with an improved yield point and elongation and with a high elastic recovery rate and copper foil adhesive strength, and provide a method of preparing the polyimide composition, a polyimide film, and a flexible copper clad laminate (FCCL).

However, goals to be achieved are not limited to those described above, and other goals not mentioned above can be clearly understood by one of ordinary skill in the art from the following description.

According to an aspect, there is provided a polyimide composition including a dianhydride, and a diamine, wherein the diamine includes an aromatic diamine, and an aliphatic diamine.

According to an embodiment, the dianhydride may include at least one of a 4,4′-(4,4′-isopropylidenediphenoxy)diphthalic anhydride (BPADA), a pyromellitic dianhydride (PMDA), a biphenyltetracarboxylic dianhydride (BPDA), a 4,4′-(hexafluoroisopropylidene)diphthalic anhydride (6FDA), an oxydiphthalic anhydride (ODPA), a 3,3′,4,4′-diphenylsulfone tetracarboxylic dianhydride (DSDA), a benzophenone tetracarboxylic dianhydride (BTDA), a biscarboxyphenyl dimethyl silane dianhydride (SiDA), a bisdicarboxyphenoxy diphenyl sulfide dianhydride (BDSDA), a sulfonyldiphthalic anhydride (SO₂DPA), an isopropylidenediphenoxy)bis(phthalic anhydride) (6HBDA), a cyclobutane tetracarboxylic dianhydride (CBDA), a cyclopentane tetracarboxylic dianhydride (CPDA), a cyclohexane tetracarboxylic dianhydride (CHDA), and a bicyclohexane tetracarboxylic dianhydride (HBPDA).

According to an embodiment, the dianhydride may be in an amount of 30% by mole (mol %) to 70 mol % in the polyimide composition.

According to an embodiment, the aromatic diamine may include at least one of 4,4′-oxydianiline (ODA), 2-(4-aminophenyl)benzoxazol-5-amine (APBOA), p-phenylenediamine (p-PDA), m-phenylenediamine (m-PDA), 2,4-toluenediamine (TDA), m-xylylenediamine (m-XDA), p-xylylenediamine (p-XDA), 1,5-diaminonaphthalene (DAN), 2,6-diaminonaphthalene (DAN), 3,5-diaminobenzoic acid (DABA), 4,4′-methylenedianiline (MDA), 2-(4-aminophenyl)-5-amino-benzimidazole (PBI), 1,3-bis(4-aminophenoxy)benzene (TPER), 2,2-bis[4-(4-aminophenoxy)phenyl]propane (BAPP), and m-toluidine.

According to an embodiment, the aliphatic diamine may include at least one of polyetheramine (PEA), a siloxane-based diamine, and a silicon-based diamine.

According to an embodiment, the diamine may be in an amount of 30 mol % to 70 mol % in the polyimide composition.

According to an embodiment, based on 100 parts by mole of the dianhydride, the aromatic diamine may be in an amount of 50 parts by mole to 90 parts by mole, and the aliphatic diamine may be in an amount of 10 parts by mole to 50 parts by mole.

According to an embodiment, the aliphatic diamine may have a molecular weight of 500 grams per mole (g/mol) to 5,000 g/mol.

According to an embodiment, the polyimide composition may further include an organic solvent. The organic solvent may include at least one of dimethylacetamide (DMAc), N-methylpyrrolidone (NMP), dimethylformamide (DMF), dimethyl sulfoxide (DMSO), cyclohexanone, acetone, diethyl acetate, and m-cresol.

According to an embodiment, the polyimide composition may be a polyamic acid or may be soluble.

According to an embodiment, a solid content of the polyimide composition may be in a range of 15% by weight (wt %) to 40 wt %.

According to another aspect, there is provided a method of preparing a polyimide composition, the method including introducing an organic solvent into a reactor at a temperature of 40° C. to 60° C., preparing a diamine solution by dissolving an aromatic diamine in the organic solvent, and introducing a dianhydride and an aliphatic diamine into the diamine solution.

According to an embodiment, the method may further include, after the introducing of the dianhydride and the aliphatic diamine, performing an imidization reaction by raising the temperature of the reactor to 160° C. or greater.

According to another aspect, there is provided a polyimide film obtained by curing the above-described polyimide composition or a polyimide composition prepared by the above-described method.

According to an embodiment, the polyimide film may be obtained by applying the polyimide composition onto a copper foil and performing drying and curing. The drying may be performed at a temperature of 140° C. to 180° C. for a period of 1 minute to 20 minutes. The curing may be performed at a temperature of 250° C. to 400° C.

According to an embodiment, the polyimide film may have an elastic recovery rate of 80% or greater in a tensile strength range of 1% to 50%.

According to an embodiment, the polyimide film may have a lamination copper foil adhesive strength of 300 gram-force/centimeter (gf/cm) or greater.

According to another aspect, there is provided an FCCL including a metal foil, and a polyimide film laminated on one surface or both surfaces of the metal foil, wherein the polyimide film is the above-described polyimide film.

Additional aspects of embodiments will be set forth in part in the description which follows and, in part, will be apparent from the description, or may be learned by practice of the disclosure.

According to embodiments, a polyimide composition with an improved yield point and elongation may be provided.

Specifically, the polyimide composition may be used to manufacture a polyimide film that may have a high elastic recovery rate and copper foil adhesive strength to be applied to an existing process, and an FCCL containing the same.

### DETAILED DESCRIPTION

Hereinafter, embodiments will be described in detail. However, various alterations and modifications may be made to the embodiments. Here, the embodiments are not construed as limited to the disclosure. The embodiments should be understood to include all changes, equivalents, and replacements within the idea and the technical scope of the disclosure.

The terminology used herein is for the purpose of describing particular embodiments only and is not to be limiting of the embodiments. The singular forms “a”, “an”, and “the” are intended to include the plural forms as well, unless the context clearly indicates otherwise. It will be further understood that the terms “comprises/comprising” and/or “includes/including” when used herein, specify the presence of stated features, integers, steps, operations, elements, components, or combinations thereof, but do not preclude the presence or addition of one or more of other features, integers, steps, operations, elements, components, or combinations thereof.

Unless otherwise defined, all terms including technical and scientific terms used herein have the same meaning as commonly understood by one of ordinary skill in the art to which the embodiments belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

In the description of embodiments, detailed description of well-known related structures or functions will be omitted when it is deemed that such description will cause ambiguous interpretation of the present disclosure. In addition, terms such as first, second, A, B, (a), (b), and the like may be used to describe components of the embodiments. These terms are used only for the purpose of discriminating one component from another component, and the nature, the sequences, or the orders of the components are not limited by the terms. It is to be understood that if a component is described as being “connected”, “coupled” or “joined” to another component, the former may be directly “connected”, “coupled”, and “joined” to the latter or “connected”, “coupled”, and “joined” to the latter via another component.

Components included in an embodiment and components having a common function will be described using the same names in other embodiments. Unless otherwise mentioned, the descriptions on the embodiments may be applicable to the following embodiments and thus, duplicated descriptions will be omitted for conciseness.

According to an embodiment, a polyimide composition may include a dianhydride, and a diamine. The diamine may include an aromatic diamine, and an aliphatic diamine.

Polyimide according to a related art is disadvantageous in a bending test due to a low yield point and elongation thereof. Since polyimide that does not have a polar group on a surface thereof is peeled off from a metal due to a decrease in durability caused by a low copper foil adhesive strength, a separate polyimide adhesive layer material and process are additionally required. Since the polyimide composition includes the dianhydride, the aromatic diamine, and the aliphatic diamine, a polyimide material with elasticity applicable to an existing process may be provided, and thus, it is possible to provide a flexible copper clad laminate (FCCL) with excellent performance, instead of using a separate adhesive layer.

According to an embodiment, the dianhydride may include at least one of a 4,4′-(4,4′-isopropylidenediphenoxy)diphthalic anhydride (BPADA), a pyromellitic dianhydride (PMDA), a biphenyltetracarboxylic dianhydride (BPDA), a 4,4′-(hexafluoroisopropylidene)diphthalic anhydride (6FDA), an oxydiphthalic anhydride (ODPA), a 3,3′,4,4′-diphenylsulfone tetracarboxylic dianhydride (DSDA), a benzophenone tetracarboxylic dianhydride (BTDA), a biscarboxyphenyl dimethyl silane dianhydride (SiDA), a bisdicarboxyphenoxy diphenyl sulfide dianhydride (BDSDA), a sulfonyldiphthalic anhydride (SO₂DPA), an isopropylidenediphenoxy)bis(phthalic anhydride) (6HBDA), a cyclobutane tetracarboxylic dianhydride (CBDA), a cyclopentane tetracarboxylic dianhydride (CPDA), a cyclohexane tetracarboxylic dianhydride (CHDA), and a bicyclohexane tetracarboxylic dianhydride (HBPDA).

Desirably, the dianhydride may be a 4,4′-(4,4′-isopropylidenediphenoxy)diphthalic anhydride (BPADA). The dianhydride may be easily used to prepare soluble polyimide due to excellent solubility in a solvent, and may maintain physical properties of polyimide, for example, a heat resistance, and a coefficient of thermal expansion (CTE).

According to an embodiment, the dianhydride may be in an amount of 30% by mole (mol %) to 70 mol % in the polyimide composition.

Desirably, the dianhydride may be in an amount of 30 mol % to 60 mol % or an amount of 40 mol % to 60 mol % in the polyimide composition.

When the amount of the dianhydride in the polyimide composition is less than 300 mol %, the heat resistance and the CTE of the polyimide may decrease.

According to an embodiment, the aromatic diamine may include at least one of 4,4′-oxydianiline (ODA), 2-(4-aminophenyl)benzoxazol-5-amine (APBOA), p-phenylenediamine (p-PDA), m-phenylenediamine (m-PDA), 2,4-toluenediamine (TDA), m-xylylenediamine (m-XDA), p-xylylenediamine (p-XDA), 1,5-diaminonaphthalene (DAN), 2,6-diaminonaphthalene (DAN), 3,5-diaminobenzoic acid (DABA), 4,4′-methylenedianiline (MDA), 2-(4-aminophenyl)-5-amino-benzimidazole (PBI), 1,3-bis(4-aminophenoxy)benzene (TPER), 2,2-bis[4-(4-aminophenoxy)phenyl]propane (BAPP), and m-toluidine.

Desirably, the aromatic diamine may be 4,4′-oxydianiline (ODA). The aromatic diamine may allow the polyimide composition to have physical properties, for example, heat resistance, and a coefficient of thermal expansion (CTE), to maintain physical properties of polyimide.

According to an embodiment, the aliphatic diamine may include at least one of polyetheramine (PEA), a siloxane-based diamine, and a silicon-based diamine.

Desirably, the aliphatic diamine may be polyetheramine (PEA). The aliphatic diamine may enhance an elongation and elastic recovery rate of the polyimide composition.

According to an embodiment, the diamine may be in an amount of 30 mol % to 70 mol % in the polyimide composition.

Desirably, the diamine may be in an amount of 30 mol % to 60 mol %, or an amount of 40 mol % to 60 mol % in the polyimide composition.

According to an embodiment, based on 100 parts by mole of the dianhydride, the aromatic diamine may be in an amount of 50 parts by mole to 90 parts by mole, and the aliphatic diamine may be in an amount of 10 parts by mole to 50 parts by mole.

When the amount of the aromatic diamine and the amount of the aliphatic diamine are out of the above ranges, the amount of the aromatic diamine may decrease, which may lead to a reduction in properties, such as a heat resistance and CTE of general polyimide. When the amount of the aliphatic diamine is less than 10 parts by mole, the elastic recovery rate may not appear. When the amount of the aliphatic diamine exceeds 50 parts by mole, it may be difficult to control a friction coefficient. Polyimide may be formed by a 1:1 reaction of a dianhydride and a diamine.

According to an embodiment, the aliphatic diamine may have a molecular weight of 500 grams per mole (g/mol) to 5,000 g/mol.

The aliphatic diamine may desirably have a molecular weight of 500 g/mol to 4,000 g/mol, 800 g/mol to 4,000 g/mol, or 800 g/mol to 3,000 g/mol.

When the molecular weight of the aliphatic diamine is less than 500 g/mol, it may be difficult to expect the elastic recovery rate. When the molecular weight of the aliphatic diamine exceeds 5,000 g/mol, a problem associated with polymerization may occur. When the molecular weight of the aliphatic diamine is within the above range, the aliphatic diamine may be a molecule with a long chain, thereby providing a polyimide composition having a high elastic recovery rate and copper foil adhesive strength.

According to an embodiment, the polyimide composition may further include an organic solvent. The organic solvent may include at least one of dimethylacetamide (DMAc), N-methylpyrrolidone (NMP), dimethylformamide (DMF), dimethyl sulfoxide (DMSO), cyclohexanone, acetone, diethyl acetate, and m-cresol.

Desirably, the organic solvent may be dimethylacetamide (DMAc), or cyclohexanone.

According to an embodiment, the polyimide composition may be a polyamic acid or may be soluble.

When the polyimide composition includes a cyclohexanone solvent, polyamic acid polyimide may be formed. When the polyimide composition includes dimethylacetamide (DMAc), soluble polyimide may be formed.

According to an embodiment, a solid content of the polyimide composition may be in a range of 15% by weight (wt %) to 40 wt %.

Desirably, the solid content may be in a range of 25 wt % to 40 wt %.

The range of the solid content may be a range of the solid content when the polyimide composition is a polyamic acid, and may be based on a molecular weight suitable for forming a polyimide film and workability during a coating of one surface of a metal foil. When the solid content is less than 15 wt %, a problem may occur in a flow during coating due to use of an unnecessary solvent or a decrease in a viscosity of a solution. When the solid content exceeds 40 wt %, it may be difficult to perform coating due to an extremely high viscosity.

According to an embodiment, a method of preparing a polyimide composition may include introducing an organic solvent into a reactor at a temperature of 40° C. to 60° C., preparing a diamine solution by dissolving an aromatic diamine in the organic solvent, and introducing a dianhydride and an aliphatic diamine into the diamine solution.

When the temperature of the reactor is within the above range, a reaction may be activated. Desirably, in the method, the polyimide composition may be prepared in the reactor at a temperature of 45° C. to 55° C. for a period of 6 hours to 24 hours. When the reaction time is less than 6 hours, an unreacted material may be present. When the reaction exceeds 24 hours, processability may decrease.

Here, features of the organic solvent, the dianhydride, the aromatic diamine, and the aliphatic diamine are the same as those described above, and accordingly, further description thereof is not repeated herein.

According to an embodiment, the method may further include, after the introducing of the dianhydride and the aliphatic diamine, performing an imidization reaction by raising the temperature of the reactor to 160° C. or greater.

In the performing of the imidization reaction, an imidization reaction of a polyamic acid composition may be performed, and a composition in the form of a polyamic acid may be prepared to be soluble through the imidization reaction.

The imidization reaction may be performed for a period of 6 hours to 12 hours at 160° C. or greater. Water may be sufficiently removed within the reaction temperature and reaction time, to perform an imidization.

According to an embodiment, a polyimide film may be obtained by curing the above-described polyimide composition or a polyimide composition prepared by the above-described method.

According to an embodiment, the polyimide film may be obtained by applying the polyimide composition onto a copper foil and performing drying and curing. The drying may be performed at a temperature of 140° C. to 180° C. for a period of 1 minute to 20 minutes. The curing may be performed at a temperature of 250° C. to 400° C.

The drying may be performed in an air atmosphere, and the curing may be performed in a nitrogen atmosphere. When the temperature and time during the drying are less than the above range, a solvent may not be properly volatilized. When the temperature and time during the drying exceed the above range, a problem associated with an oxidization may occur in the air atmosphere or processability may decrease.

According to an embodiment, the polyimide film may have an elastic recovery rate of 80% or greater in a tensile strength range of 1% to 50%.

The elastic recovery rate may be a degree to which it returns to an initial length thereof after being stretched a predetermined distance. The elastic recovery rate of 80% or greater may indicate a high yield point and elongation. While a yield point of a polyimide film according to a related art is less than 5%, the polyimide film may have a yield point of 10% to 15%. Here, since an occurrence of cracks due to repeated bending is prevented due to an excellent flexibility of the polyimide film, and the polyimide film exhibits excellent flexural properties, the polyimide film may be suitable for use as a flexible substrate material.

According to an embodiment, the polyimide film may have a lamination copper foil adhesive strength of 300 gram-force/centimeter (gf/cm) or greater.

When the copper foil adhesive strength is greater than or equal to 300 gf/cm, peeling may not occur while securing an excellent copper foil adhesive strength during a formation of an FCCL, and an additional adhesive layer may not be required.

The polyimide film may have a CTE of 100 parts per million per Kelvin (ppm/K) to 300 ppm/K and a friction coefficient of 0.7 or less.

When the CTE is out of the above range, a problem associated with a dimensional stability may occur during manufacturing of an FCCL. When the friction coefficient exceeds 0.7, a process drivability may decrease.

The polyimide film may have a high elastic recovery and copper foil adhesive strength, and thus, an excellent FCCL that does not require an additional process may be provided.

According to an embodiment, an FCCL may include a metal foil, and a polyimide film laminated on one surface or both surfaces of the metal foil. The polyimide film may be the polyimide film described above.

The polyimide film may be laminated by coating one surface or both surfaces of the metal foil with the polyimide composition.

The coating may include, for example, slot-die coating, comma coating, reverse comma coating, cast coating, knife coating, roll coating, curtain coating, or dip coating.

The polyimide film may have a thickness of 5 micrometers (m) to 100 m. The FCCL including a polyimide film having a high elastic recovery and copper foil adhesive strength according to an embodiment may be suitable to be applied as an FCCL material that is a core material for electronic components in the fifth generation (5G) era.

Hereinafter, the present disclosure will be described in more detail with reference to examples.

However, the following examples are only for illustrating the present disclosure, and the present disclosure is not limited to the following examples.

### Example 1

A dimethylacetamide (DMAc) solvent was introduced into a reactor at 50° C., and 70 mol % of 4,4′-oxydianiline (ODA), an aromatic diamine, was introduced thereto and dissolved. 100 mol % of 4,4′-(4,4′-isopropylidenediphenoxy)diphthalic anhydride (BPADA), a dianhydride, was added to a solution in which a diamine was dissolved, and was sufficiently dissolved, and 30 mol % of polyetheramine (PEA), an aliphatic diamine was introduced thereto, to obtain a polyimide composition.

### Example 2

A polyimide composition was obtained in the same manner as in Example 1, except that 75 mol % of ODA and 25 mol % of PEA were added.

### Example 3

A polyimide composition was obtained in the same manner as in Example 1, except that 90 mol % of BPADA and 10 mol % of pyromellitic dianhydride (PMDA) as dianhydrides were added.

The polyimide compositions obtained in Examples 1 to 3 were applied onto a copper foil, and drying was performed for 10 minutes at 160° C. in an air atmosphere. Subsequently, the temperature was slowly raised from room temperature to 300° C. in a nitrogen atmosphere, and curing was performed, to manufacture a polyimide film.

Physical properties of a film according to each composition were measured and shown in Tables 1 and 2.

### (1) ELASTIC RECOVERY RATE

A polyimide film obtained by removing a copper foil layer with an iron(II) chloride (FeCl₂) solution was cut into a length of 150 millimeters (mm) and a width of 10 mm, to prepare a measurement specimen. Subsequently, measurement was performed using MCT-1150 (AND, Co., Ltd.) at a grip distance of 100 mm, a speed of 50 mm/min, a tensioning range of 5 to 50% (5 mm to 50 mm), and a load cell of 500 N.

### (2) CTE

A polyimide film obtained by removing a copper foil layer with an iron(II) chloride (FeCl₂) solution was cut into a length of 4 mm and a width of 50 mm, to prepare a measurement specimen. Subsequently, tension of 30 N was applied using Hitachi 7100, and a CTE at a temperature of 100° C. to 150° C. was measured.

### (3) FRICTION COEFFICIENT

A polyimide film obtained by removing a copper foil layer with an iron(II) chloride (FeCl₂) solution was cut into a length of 100 mm and a width of 50 mm, to prepare a measurement specimen. Subsequently, after the measurement specimen was fixed to equipment using HEIDON Type 10, a section in which a sensor stops was measured.

### (4) LAMINATION COPPER FOIL ADHESIVE STRENGTH

A polyimide film obtained by removing a copper foil layer with an iron(II) chloride (FeCl₂) solution was cut into a length of 100 mm and a width of 10 mm, to prepare a measurement specimen. Subsequently, measurement was performed using Instron 3345 at a grip distance of 50 mm, and a speed of 50.8 mm/min.

TABLE 1

| | Elastic recovery rate (%) | CTE | Lamination copper foil | Friction |
|---|---|---|---|---|
| Classification | after stretching by 10% | (ppm/K) | adhesive strength (gf/cm) | coefficient |
| Example 1 | 86.0 | 85.3 | 770 | 0.56 |
| Example 2 | 87.3 | 79.9 | 650 | 0.50 |
| Example 3 | 84.9 | 83.3 | 650 | 0.44 |

TABLE 2

| | Elastic recovery rate (%) | CTE | Lamination copper foil | Friction |
|---|---|---|---|---|
| Classification | after stretching by 10% | (ppm/K) | adhesive strength (gf/cm) | coefficient |
| Example 1 | 84.3 | 103.5 | 1,100 | 0.61 |
| Example 2 | 81.2 | 88.5 | 890 | 0.59 |
| Example 3 | 83.0 | 90.2 | 800 | 0.55 |

Table 1 shows results of physical properties of a film using a polyamic acid polyimide composition, and Table 2 shows results of physical properties of a film using a soluble polyimide composition.

Referring to Tables 1 and 2, it can be confirmed that the elastic recovery rate is greater than or equal to 80% and the lamination copper foil adhesive strength is greater than or equal to 600 gf/cm, and that the polyimide film according to an embodiment has an excellent elastic recovery rate and copper foil adhesive strength.

While the embodiments are described, it will be apparent to one of ordinary skill in the art that various alterations and modifications in form and details may be made in these embodiments without departing from the spirit and scope of the claims and their equivalents. For example, suitable results may be achieved if the described techniques are performed in a different order, and/or if components in a described system, architecture, device, or circuit are combined in a different manner, and/or replaced or supplemented by other components or their equivalents.

Therefore, other implementations, other embodiments, and equivalents to the claims are also within the scope of the following claims.

What is claimed is:

1. A polyimide composition comprising:
a dianhydride; and
a diamine,
wherein the diamine comprises an aromatic diamine, and an aliphatic diamine.

2. The polyimide composition of claim 1, wherein the dianhydride comprises at least one selected from a group consisting of a 4,4′-(4,4′-isopropylidenediphenoxy)diphthalic anhydride (BPADA), a pyromellitic dianhydride (PMDA), a biphenyltetracarboxylic dianhydride (BPDA), a 4,4′-(hexafluoroisopropylidene)diphthalic anhydride (6FDA), an oxydiphthalic anhydride (ODPA), a 3,3′,4,4′-diphenylsulfone tetracarboxylic dianhydride (DSDA), a benzophenone tetracarboxylic dianhydride (BTDA), a biscarboxyphenyl dimethyl silane dianhydride (SiDA), a bisdicarboxyphenoxy diphenyl sulfide dianhydride (BDSDA), a sulfonyldiphthalic anhydride (SO₂DPA), an isopropylidenediphenoxy)bis(phthalic anhydride) (6HBDA), a cyclobutane tetracarboxylic dianhydride (CBDA), a cyclopentane tetracarboxylic dianhydride (CPDA), a cyclohexane tetracarboxylic dianhydride (CHDA), and a bicyclohexane tetracarboxylic dianhydride (HBPDA).

3. The polyimide composition of claim 1, wherein the dianhydride is in an amount of 30% by mole (mol %) to 70 mol % in the polyimide composition.

4. The polyimide composition of claim 1, wherein the aromatic diamine comprises at least one selected from a group consisting of 4,4′-oxydianiline (ODA), 2-(4-aminophenyl)benzoxazol-5-amine (APBOA), p-phenylenediamine (p-PDA), m-phenylenediamine (m-PDA), 2,4-toluenediamine (TDA), m-xylylenediamine (m-XDA), p-xylylenediamine (p-XDA), 1,5-diaminonaphthalene (DAN), 2,6-diaminonaphthalene (DAN), 3,5-diaminobenzoic acid (DABA), 4,4′-methylenedianiline (MDA), 2-(4-aminophenyl)-5-amino-benzimidazole (PBI), 1,3-bis(4-aminophenoxy)benzene (TPER), 2,2-bis[4-(4-aminophenoxy)phenyl]propane (BAPP), and m-toluidine.

5. The polyimide composition of claim 1, wherein the aliphatic diamine comprises at least one selected from a group consisting of polyetheramine (PEA), a siloxane-based diamine, and a silicon-based diamine.

6. The polyimide composition of claim 1, wherein the diamine is in an amount of 30 mol % to 70 mol % in the polyimide composition.

7. The polyimide composition of claim 1, wherein, based on 100 parts by mole of the dianhydride,
the aromatic diamine is in an amount of 50 parts by mole to 90 parts by mole, and
the aliphatic diamine is in an amount of 10 parts by mole to 50 parts by mole.

8. The polyimide composition of claim 1, wherein the aliphatic diamine has a molecular weight of 500 grams per mole (g/mol) to 5,000 g/mol.

9. The polyimide composition of claim 1, further comprising:
an organic solvent,
wherein the organic solvent comprises at least one selected from a group consisting of dimethylacetamide (DMAc), N-methylpyrrolidone (NMP), dimethylformamide (DMF), dimethyl sulfoxide (DMSO), cyclohexanone, acetone, diethyl acetate, and m-cresol.

10. The polyimide composition of claim 9, wherein the polyimide composition is a polyamic acid or is soluble.

11. The polyimide composition of claim 9, wherein a solid content of the polyimide composition is in a range of 15% by weight (wt %) to 40 wt %.

12. A method of preparing a polyimide composition, the method comprising:
introducing an organic solvent into a reactor at a temperature of 40° C. to 60° C.;
preparing a diamine solution by dissolving an aromatic diamine in the organic solvent; and
introducing a dianhydride and an aliphatic diamine into the diamine solution.

13. The method of claim 12, further comprising, after the introducing of the dianhydride and the aliphatic diamine:
performing an imidization reaction by raising the temperature of the reactor to 160° C. or greater.

14. A polyimide film obtained by curing the polyimide composition of claim 1 or a polyimide composition prepared by the method of claim 12.

15. The polyimide film of claim 14, wherein
the polyimide film is obtained by applying the polyimide composition onto a copper foil and performing drying and curing,
the drying is performed at a temperature of 140° C. to 180° C. for a period of 1 minute to 20 minutes, and
the curing is performed at a temperature of 250° C. to 400° C.

16. The polyimide film of claim 14, wherein the polyimide film has an elastic recovery rate of 80% or greater in a tensile strength range of 1% to 50%.

17. The polyimide film of claim 14, wherein the polyimide film has a lamination copper foil adhesive strength of 300 gram-force/centimeter (gf/cm) or greater.
